(19) United States
(12) Patent Application Publication
(10) Pub. No.: US 2011/0161774 A1
(43) Pub. Date: Jun. 30, 2011

(54) SEMICONDUCTOR MEMORY SYSTEM HAVING ECC CIRCUIT AND METHOD OF CONTROLLING THEREOF

(75) Inventors: Young Kyun SHIN, Ichon-shi (KR); Sung Hee Hong, Ichon-shi (KR); Dae Hee Yi, Seoul (KR); Jong Gah Kim, Seoul (KR)

(73) Assignees: Hynix Semiconductor Inc., Ichon-shi (KR); PaxDisk Co., Ltd., Seoul (KR)

(21) Appl. No.: 12/947,203

(22) Filed: Nov. 16, 2010

(30) Foreign Application Priority Data
Dec. 24, 2009 (KR) 10-2009-0130740

(51) Int. Cl. H03M 13/05; G06F 11/10

(52) U.S. Cl. 714/755; 714/E11.034

(57) ABSTRACT

A semiconductor storage system includes: a memory region having a plurality of memory cells; and a memory controller having a data control unit. The data control unit includes a write control unit which, during a write operation, performs first error check correction (ECC) encoding on an input data to generate a first encoded input data, compresses the first encoded input data to generate a compressed input data, and performs second ECC encoding on the compressed input data to generate a second encoded input data. The write control unit then writes the second encoded input data into the memory region as a write data.

### CROSS-REFERENCES TO RELATED APPLICATION

The present application claims priority under 35 U.S.C. §119(a) to Korean Application No. 10-2009-0130740, filed on Dec. 24, 2009, which is incorporated by reference in its entirety as if set forth in full.

### BACKGROUND OF THE INVENTION

1. Technical Field

Various embodiments relate to a semiconductor storage system and a method of controlling thereof, and more particularly, to a semiconductor storage system having an ECC circuit and the method of controlling thereof.

2. Related Art

Nonvolatile memories are typically used as a storage memory in various portable information devices. Recently, a personal computer (PC) which is equipped with a solid state drive (SSD) using a NAND flash memory instead of a hard disk drive (HDD) has been introduced in the market, and the solid state drives (SSDs) will dominate the hard disk drives (HDDs) in the storage market in the near future.

When data in a semiconductor storage system such as the solid state drive (SSD) is updated, a delete operation in a selected data storage area should be conducted before performing a write operation due to the characteristics of the flash memory. Therefore, frequent updates of a memory cell may cause rapid aging of the memory cell due to the frequent delete and write operations. Accordingly, if a data size is increased, an aging area is increased. In addition, if the data size is increased, a write busy time for the data in the flash memory region is increased, and thus a data transfer time is also increased. Moreover, when the semiconductor storage system using a NAND flash memory writes data in the memory cell, a threshold value level of another cell which has previously stored data can be changed due to an erroneous operation or the write operation of the neighboring cell. Therefore, if the threshold value level is changed, the accuracy of a data read operation may be decreased.

As such, a data transfer method which can store more data with accuracy in a limited memory region and use the memory cell for a longer time is highly needed.

### SUMMARY OF THE INVENTION

The embodiments of the present invention include a semiconductor storage system correcting a data error.

The embodiments of the present invention include a method of controlling the semiconductor storage system correcting a data error.

In one embodiment of the present invention, a semiconductor storage system includes: a memory region having a plurality of memory cells; and a memory controller having a data control unit. The data control unit includes a write control unit which is configured to, during a write operation, perform first error check correction (ECC) encoding on an input data to generate a first encoded input data, compress the first encoded input data to generate a compressed input data, perform second ECC encoding on the compressed input data to generate a second encoded input data, and write the second encoded input data into the memory region as a write data.

In another embodiment of the present invention, a method of controlling a semiconductor storage system includes: (a) receiving an input data; (b) performing first error check correction (ECC) encoding on the input data to generate a first encoded input data; (c) compressing the first encoded input data to generate a compressed input data; (d) performing second ECC encoding on the compressed input data to generate a second encoded input data; and (e) writing the second encoded input data into a memory region in the semiconductor storage system.

In still another embodiment of the present invention, a semiconductor memory device includes: a host interface; a micro control unit configured to receive an input data via the host interface; a memory controller with a data control unit; and a memory region having a plurality of memory cells. The data control unit includes a write control unit configured to perform first error correction encoding on the input data to generate a first encoded input data and a first redundancy data, and compress the first encoded input data and the first redundancy data to generate a compressed input data.

### BRIEF DESCRIPTION OF THE DRAWINGS

Features, aspects, and embodiments are described in conjunction with the attached drawings, in which;

FIG. 1 is a block diagram showing a configuration of a semiconductor storage system according to an embodiment of the present invention;

FIG. 2 is a block diagram showing a configuration of a data control unit of FIG. 1;

FIG. 3 is a block diagram showing a configuration of a data structure relation of FIG. 2; and

FIGS. 4 and 5 are flow charts showing a method of controlling the semiconductor storage system according to an embodiment of the present invention.

### DETAILED DESCRIPTION OF THE PREFERRED EMBODIMENTS

Hereinafter, a semiconductor storage system having an ECC circuit and a method of controlling thereof, according to the present invention, will be described below with reference to the accompanying drawings through preferred embodiments.

Further, each block of the block diagrams may represent a module, segment, or portion of code, which comprises one or more executable instructions for implementing the specified logical function(s). It should also be noted that in some alternative implementations, the functions noted in the blocks may occur out of order. For example, two blocks shown in succession may in fact be executed substantially concurrently or the blocks may sometimes be executed in reverse order depending upon the functionality involved.

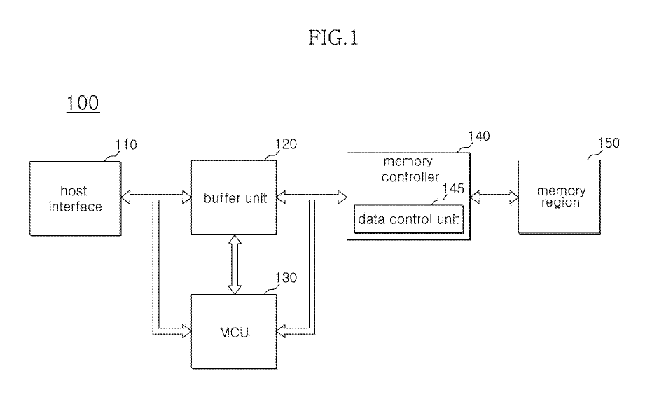

Hereinafter, a semiconductor storage system according to one embodiment of the present invention will now be described with reference to FIG. 1.

FIG. 1 is a block diagram showing a configuration of a semiconductor storage system 100 according to the embodiment of the present invention. Here, the semiconductor storage system 100 is exemplified as a system using a NAND flash memory.

Referring to FIG. 1, the semiconductor storage system 100 includes a host interface 110, a buffer unit 120, a micro control unit (MCU) 130, a memory controller 140, and a memory region 150.

The host interface 110 is coupled to the buffer unit 120. The host interface 110 receives/transfers a control command, an address signal, and a data signal between an external host (not shown) and the buffer unit 120. The method of interfacing between the external host (not shown) and the host interface 110 may be one of Serial Advanced Technology Attachment (SATA), Parallel Advanced Technology Attachment (PATA), SCSI, Express Card, and PCI-Express, but the embodiment is not limited thereto.

The buffer unit 120 buffers an output signal from the host interface 110, or temporarily stores mapping information between a logical address and a physical address, block allocating information of the memory region, the number of deletion times of the block, and data received from outside. The buffer unit 120 may be a buffer using a static random access memory (SRAM) or a dynamic random access memory (DRAM).

The micro control unit (MCU) 130 receives/transfers the control command, the address signal, the data signal, etc. from/to the host interface 110, and controls the memory controller 140 in response to those signals.

Meanwhile, the memory controller 140 includes a data control unit 145. Like a conventional controller, the memory controller 140 controls the semiconductor storage system 100 such that when the memory controller 140 receives an input data and a write command from the host interface 110, the semiconductor storage system 100 writes the input data in the memory region 150. Similarly, the memory controller 140 controls the semiconductor storage system 100 such that when the memory controller 140 receives a read command from the host interface 110, the semiconductor storage system 100 reads data from the memory region 150 and output the data externally.

During a write operation, the data control unit 145 generates a first parity, i.e., one or more first parity bits, for verifying an error in the data received from the host interface 110. The data control unit 145 then compresses the verification result, e.g., the first parity bits and the data received from the host interface 110, and generates a second parity, i.e., one or more second parity bits, for re-verifying an error in the compressed data. The data control unit 145 then writes the compressed data together with the one or more second parity bits in the memory region 150. Reversely, during a read operation, the data control unit 145 verifies an error in the compressed data from the memory region 150 using the one or more second parity bits, and decompresses the verification result, and re-verifies a data error, and then provides the output to the host interface 110. The one or more first and second parity bits are preferably single-bit data information.

In detail, during a write operation, the data control unit 145 performs first ECC (Error Check Correction) encoding, and then compresses the data together with the first parity bits generated from the first ECC encoding, and then performs second ECC encoding on the compressed data.

As described above, the read operation can be explained as a reverse sequence of the write operation. For example, during the read operation, the data control unit 145 performs first ECC decoding to verify an error using the compressed data stored in the memory region 150 and one or more second parity bits, and decompresses the verification result, e.g., the compressed data and the first parity bits, to restore the data structure prior to the compression during the write operation. Then, the semiconductor storage system 100 performs second ECC decoding on the decompressed data to re-verify an error, and provides the result to the host interface 110 to facilitate data reading with an enhanced reliability.

As such, according to the embodiment, an error correction rate of data can be enhanced by performing ECC encoding and ECC decoding twice. Moreover, the semiconductor storage system 100 provides the compressed data to the memory region 150 to reduce a write busy time and store more data in the limited memory region 150.

The memory controller 140 controls the memory region 150 such that the memory region 150 can perform the write, delete, and read operations. Here, the memory region 150 may be the NAND flash memory. In the embodiment, a cell of the NAND flash memory may be a single level cell (SLC) or a mufti-level cell (MLC).

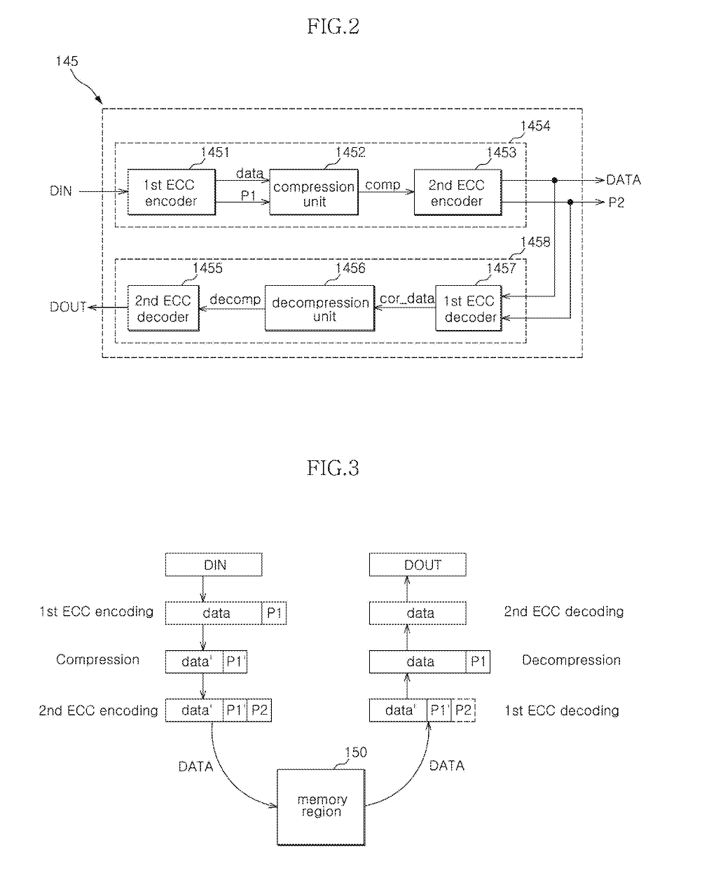

FIG. 2 is a block diagram showing a configuration of the data control unit 145 of FIG. 1, and FIG. 3 is a block diagram showing a configuration of a data structure relation between the memory region 150 and the data control unit 145 of FIG. 2.

Referring to FIGS. 2 and 3, the data control unit 145 includes a write control unit 1454 and a read control unit 1458.

Firstly, the write control unit 1454 includes a first ECC encoder 1451, a compression unit 1452, and a second ECC encoder 1453.

As shown in FIGS. 2 and 3, the first ECC encoder 1451 encodes an input data ‘DIN’ to generate a cell data ‘data’ and a first parity ‘P1’. In general, ECC encoding is a technique which encodes data so as to verify and correct an error which may occur in a data transmission operation. That is, the ECC encoding is typically performed to add parity information, i.e., information used for verification, to an original data so that a semiconductor storage system can detect and correct an error when a signal is weakened or it is difficult to receive the complete signal due to an external electric wave while transferring the data through a communication wire. Here, it is exemplified that Reed Solomon code is used as a first ECC encoding algorithm, but the embodiment is not limited thereto, and other error detection/correction coding scheme such as Hamming code and Triple Modular Redundancy may be alternatively used.

The compression unit 1452 compresses both the cell data ‘data’ and the first parity ‘P1’, which are encoded result of the first ECC encoder 1451, to provide a compressed data ‘comp’. As a compression algorithm, for example, there is an algorithm which memorizes repetition times of a repetitive letter, or reduces a length of a repetitive word, or reduces space between data as a specifically developed coding technique. Therefore, all of the various algorithms to reduce a data size may be included as the compression algorithm. Using such an algorithm, data may be compressed and the first parity ‘P1’ which is the result of the data encoding may be compressed as well.

As shown in FIG. 3, the second ECC encoder 1453 performs second ECC encoding on the compressed data ‘comp’ to generate a final data ‘DATA’ and a second parity ‘P2’. Here, it is exemplified that Bose-Chaudhuri-Hocquenghem (BCH) algorithm is used as the second ECC encoding algorithm. Meanwhile, it is exemplified here that the second parity ‘P2’ generated from the second ECC encoder 1453 is stored in a part of a storage area (not shown) of the data control unit 145.

As such, during the write operation, the semiconductor storage system 100 performs the ECC encoding twice, thereby enhancing a reliability of data transmission, and the semiconductor storage system 100 may use the limited memory region (refer to 150 of FIG. 1) efficiently by providing the compressed data.

Meanwhile, the read control unit 1458 includes a first ECC decoder 1457, a decompression unit 1456, and a second ECC decoder 1455.

During the read operation, the first ECC decoder 1457 verifies a data error by using the compressed data, e.g., ‘comp’, and the second parity ‘P2’, and corrects the data based on the verification result, and then provides a corrected data ‘cor_data’. The first ECC decoder 1457 is included to decode data as a counterpart of the second ECC encoder 1453, and it is exemplified that the first ECC decoder 1457 uses the BCH algorithm as a decoding technique.

The decompression unit 1456 decompresses the result of the first ECC decoding to generate a decompressed data ‘decomp’ as the result of the first ECC encoder 1451, so that the semiconductor storage system 100 may restore the data structure prior to the compression by the compression unit 1452. Here, a principle of the decompression unit 1456 may be the opposite to a principle of the compression unit 1452, and those skilled in the art may readily implement the decompression unit 1456, thus details will be omitted thereon.

Next, as shown in FIGS. 2 and 3, the second ECC decoder 1455 performs second ECC decoding on the decompression result. That is, by using the cell data ‘data’ and the first parity ‘P1’, the first ECC decoder 1455 verifies a data error, and corrects the data based on the verification result, and then provides an output data ‘DOUT’. The second ECC decoder 1455 is included to decode data as a counterpart of the first ECC encoder 1451, and Reed Solomon may be used as a decoding technique of the second ECC decoder 1455.

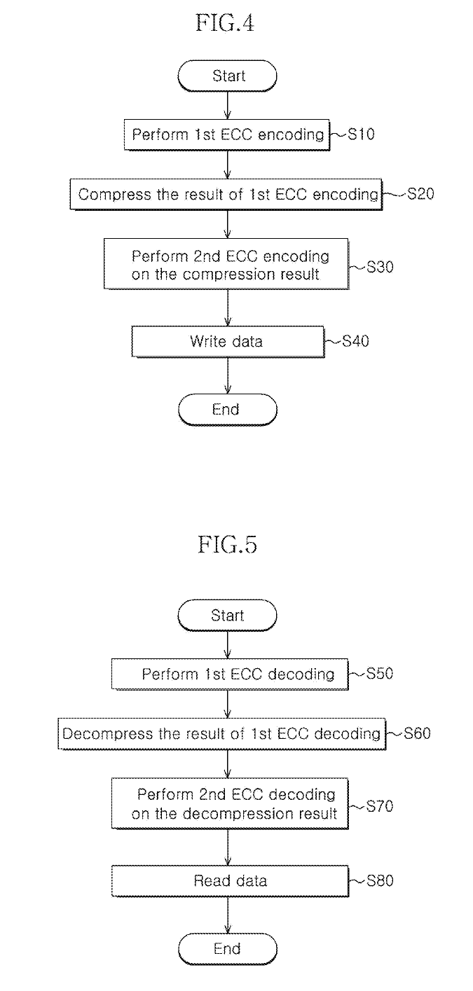

FIGS. 4 and 5 are flow charts showing a method of controlling the semiconductor storage system 100 according to the embodiment for the write operation and the read operation.

Referring to FIGS. 1 to 4, during the write operation, the semiconductor storage system performs the first ECC encoding on the input data ‘DIN’ (S10).

Specifically, the semiconductor storage system performs the first ECC encoding to generate the cell data ‘data’ and the first parity ‘P1’.

The semiconductor storage system compresses the result of the first ECC encoding (S20).

Therefore, the data can be compressed, and the first parity ‘P1’ which is a result of the encoding of the data may be compressed as well.

The semiconductor storage system performs the second ECC encoding on the compression result (S30).

That is, the second ECC encoding is performed to verify a data error which may occur in the compression operation and to enhance an error correction rate of data which will be written in the memory cell region (refer to 150 in FIG. 1).

The semiconductor storage system writes data which is a final result (S40).

Next, referring to FIGS. 1 to 5, during the read operation, an operation of the semiconductor storage system 100 will now be described.

During the read operation, the semiconductor storage system performs the first ECC decoding on data from the memory cell region (refer to 150 in FIG. 1) (S50).

In detail, the semiconductor storage system reads the data from the memory cell region (refer to 150 in FIG. 1), and verifies a data error by using the second parity ‘P2’ stored in the data control unit (refer to 145 in FIG. 1), and corrects the data if there is an error.

The semiconductor storage system decompresses the result of the first ECC decoding (S60).

That is, the semiconductor storage system decompresses data which is the result of the first ECC decoding, thereby restoring the data structure before being compressed.

The semiconductor storage system performs the second ECC decoding on the decompression result (S70).

The semiconductor storage system verifies an error of the decompressed data, and corrects the data if there is an error.

The semiconductor storage system provides corrected data or uncorrected data to the host interface (refer to 150 in FIG. 1) as the output data ‘DOUT’, and completes the data read operation (S80).

As such, according to the embodiment, the semiconductor storage system performs the first ECC encoding on data, and compresses the result itself to perform the second ECC encoding, thereby capable of enhancing the error correction rate of data, and performs the second ECC encoding on the compression result, thereby capable of reducing a burden of error correction. Moreover, the semiconductor storage system stores the compressed data, thereby capable of efficiently using the limited memory region.

While certain embodiments have been described above, it will be understood to those skilled in the art that the embodiments described are by way of example only. Accordingly, the device and method described herein should not be limited based on the described embodiments. Rather, the apparatus described herein should only be limited in light of the claims that follow when taken in conjunction with the above description and accompanying drawings.

1. A semiconductor storage system comprising:
a memory region having a plurality of memory cells; and
a memory controller having a data control unit;
wherein the data control unit includes a write control unit which is configured to, during a write operation, perform first error check correction (ECC) encoding on an input data to generate a first encoded input data, compress the first encoded input data to generate a compressed input data, perform second ECC encoding on the compressed input data to generate a second encoded input data, and write the second encoded input data into the memory region as a write data.

2. The semiconductor storage system of claim 1, wherein the data control unit further includes a read control unit which is configured to, during a read operation, read an output data from the memory region, perform first ECC decoding on the output data to generate a first decoded output data, decompresses the first decoded output data to generate a decompressed output data, perform second ECC decoding on the decompressed output data to generate a second decoded output data, and output the second decoded output data as a read data.

3. The semiconductor storage system of claim 2, wherein the write control unit includes:
a first encoder configured to encode the input data to provide one or more first parity bits;
a compression unit configured to compress the result of the first encoder; and
a second encoder configured to encode the result of the compression unit to provide one or more second parity bits.

4. The semiconductor storage system of claim 2, wherein the read control unit includes:
a first decoder configured to decode the data in the memory region using the one or more second parity bits;
a decompression unit configured to decompress the result of the first decoder; and
a second decoder configured to decode the result of the decompression unit using the one or more first parity bits.

5. The semiconductor storage system of claim 2, wherein the semiconductor storage system comprises a NAND flash memory.

6. The semiconductor storage system of claim 3, wherein the one or more first parity bits consist of a single bit.

7. The semiconductor storage system of claim 3, wherein the one or more second parity bits consist of a single bit.

8. A method of controlling a semiconductor storage system comprising:
receiving an input data;
performing first error check correction (ECC) encoding on the input data to generate a first encoded input data;
compressing the first encoded input data to generate a compressed input data;
performing second ECC encoding on the compressed input data to generate a second encoded input data; and
writing the second encoded input data into a memory region in the semiconductor storage system.

9. The method of claim 8, further comprising the steps of:
reading an output data from the memory region in the semiconductor storage system;
performing first ECC decoding on the output data to generate a first decoded output data;
decompressing the first decoded output data to generate a decompressed output data;
performing second ECC decoding on the decompressed output data to generate a second decoded output data; and
outputting the second decoded output data as a read data.

10. The method of claim 8, wherein performing the first ECC encoding comprises encoding the input data to provide one or more first parity bits; and
performing the second ECC encoding comprises encoding the compressed input data to provide one or more second parity bits.

11. The method of claim 10, wherein performing the first ECC decoding comprises performing the first ECC decoding on the output data using the one or more second parity bits; and performing the second ECC decoding comprises performing the second ECC decoding on the decompressed output data using the one or more first parity bits.

12. The method of claim 8, wherein the first ECC encoding comprises Reed Solomon coding algorithm.

13. The method of claim 8, wherein the semiconductor storage system comprises a NAND flash memory.

14. The method of claim 10, wherein the one or more first parity bits consist of a single bit.

15. The method of claim 10, wherein the one or more second parity bits consist of a single bit.

16. A semiconductor memory device comprising:
a host interface;
a micro control unit configured to receive an input data via the host interface;
a memory controller with a data control unit; and
a memory region having a plurality of memory cells;
wherein the data control unit includes a write control unit configured to perform first error correction encoding on the input data to generate a first encoded input data and a first redundancy data, and compress the first encoded input data and the first redundancy data to generate a compressed input data.

17. The semiconductor memory device of claim 16, wherein the write control unit is further configured to perform second error correction encoding on the compressed input data to generate a second encoded input data and a second redundancy data, and write the second encoded input data and the second redundancy data into some of the memory cells.

18. The semiconductor memory device of claim 17, wherein the data control unit further includes a read control unit which is configured to read an output data from the memory region, perform first error correction decoding on the output data using the second redundancy data to generate a first decoded output data, decompresses the first decoded output data to generate a decompressed output data and the first redundancy data, and perform second error correction decoding on the decompressed output data using the first redundancy data to generate a second decoded output data.

19. The semiconductor memory device of claim 16, wherein the first redundancy data comprises a single parity bit.

20. The semiconductor memory device of claim 16, wherein the second redundancy data comprises a single parity bit.
